(19) United States
(12) Patent Application Publication
(10) Pub. No.: US 2014/0014039 A1
(43) Pub. Date: Jan. 16, 2014

(54) VAPOR-PHASE GROWTH APPARATUS

(71) Applicants: Kazuki Naito, Tokyo (JP); Akira Yamaguchi, Tokyo (JP); Kosuke Uchiyama, Tama-city (JP); Jun Yamamoto, Tama-city (JP)

(72) Inventors: Kazuki Naito, Tokyo (JP); Akira Yamaguchi, Tokyo (JP); Kosuke Uchiyama, Tama-city (JP); Jun Yamamoto, Tama-city (JP)

(73) Assignees: TN EMC LTD., Tama-city (JP); Taiyo Nippon Sanso Corporation, Tokyo (JP)

(21) Appl. No.: 14/008,401

(22) PCT Filed: Mar. 16, 2012
(86) PCT No.: PCT/JP2012/056924

§ 371 Date: Sep. 27, 2013

(30) Foreign Application Priority Data
Mar. 31, 2011 (JP) 2011-077390

(51) Int. Cl. C23C 16/458

(52) U.S. Cl. CPC C23C 16/458
USPC 118/730

(57) ABSTRACT

The present invention provides a vapor-phase growth apparatus, including: a reaction furnace in which a susceptor is removably installed, and in which vapor-phase growth is conducted; a transport robot which transports the aforementioned susceptor; a glove box which accommodates the pertinent transport robot and the aforementioned reaction furnace; an exchange table which is set up inside the pertinent glove box, and on which a susceptor is temporarily mounted during susceptor replacement; and an exchange box which is provided in a side wall of the aforementioned glove box, and in which susceptor replacement is conducted; and wherein the aforementioned exchange table comprises a positioning device which rotates upon mounting of the aforementioned susceptor, and which determines a position of the aforementioned susceptor in a rotational direction by stopping at a prescribed rotational position.

### TECHNICAL FIELD

The present invention relates to a vapor-phase growth apparatus which deposits a thin film on a substrate by supplying a vapor-phase raw material while heating the substrate.

Priority is claimed on Japanese Patent Application No. 2011-077390, filed Mar. 31, 2011, the content of which is incorporated herein by reference.

### BACKGROUND ART

With respect to vapor-phase growth apparatuses in which raw material gas is supplied to the interior of a reaction chamber in a state where a substrate held by a susceptor is heated to a prescribed temperature, and a thin film is deposited (grown) on the surface of the aforementioned substrate, a vapor-phase growth apparatus is known which—in order to evenly form thin film on a plurality of substrate—is provided with a mechanism that not only rotates the susceptor, but also rotates substrate mounting members (substrate trays) on which substrates are mounted in conjunction with rotation of the pertinent susceptor, and that causes rotation and revolution of the substrates during film formation (see Patent Document 1).

FIG. 4 is a cross-sectional view of a vapor-phase growth apparatus 70 disclosed in Patent Document 1. The vapor-phase growth apparatus 70 disclosed in Patent Document 1 is provided with a susceptor 73 consisting of discoid carbon inside a flat cylindrical chamber 72 furnished with a gas inlet tube 71 at its top center, multiple substrate holders 74 concentrically arranged at equal intervals on an outer peripheral portion of the pertinent susceptor 73, and a partition plate 76 that is disposed opposite and above the susceptor 73 to divide the interior of the chamber 72 into upper and lower sections, and that forms a reaction chamber 75 on the susceptor 73 side.

The chamber 72 is given a divided form by a chamber body 77 wherein an upper part on the side opposite the susceptor is open, and a chamber cover 78 that is attached in an airtight manner via an O-ring to the top of a circular wall of the pertinent chamber body 77. At the bottom center of the chamber body 77, there is a construction in which a rotary drive shaft 79 is provided to rotate the susceptor 73, and in which the susceptor 73 is rotated by the pertinent rotary drive shaft 79, whereby the substrate holder 74 that holds the substrate 80 revolves around the center of the susceptor 73, and is rotated by a rotating gear mechanism provided at the periphery of the susceptor 73.

Underneath the substrate holder 74, a heater 81 for heating the substrate 80 is disposed in an annular shape, and an annular exhaust channel 82 is provided at the outer peripheral side of the susceptor 73.

As the interior of the chamber in which the susceptor 73 is disposed is contamination-averse, it is accommodated within a box called a glove box, and cannot be exposed to the outside air. Consequently, replacement of the susceptor 73 is conducted in an exchange box that is provided on a side face of the glove box, and that has an internal environment that can be adjusted to a nitrogen atmosphere.

Patent Document 2 records an example of conducting susceptor exchange by an automatic transport device. Patent Document 2 does not record the particulars of the transport of the susceptor 73 itself, but they are roughly as follows.

A susceptor in a reaction furnace is held by a transport robot disposed within a glove box, and is transported to the exchange box. Meanwhile, a second susceptor that is on standby in the exchange box is conveyed from the exchange box to an exchange table. After mounting substrates onto the substrate holders (substrate trays) on the exchange table, the susceptor is transported from the exchange table to the reaction furnace. In this manner, a double operation is conducted wherein a first susceptor is on standby in the exchange box while growth is being conducted on a second susceptor.

### PRIOR ART REFERENCES

### Patent Documents

Patent Document 1: Japanese Unexamined Patent Application No. 2008-262967

Patent Document 2: Japanese Unexamined Patent Application No. 2010-255083

### DISCLOSURE OF THE INVENTION

### Problems that the Invention is to Solve

The transport robot in the conventional example transports a susceptor without alteration of the position (phase) of placement of the susceptor inside the exchange box, and sets it in the chamber.

Setting of a susceptor in the chamber requires accurate alignment of a fitting part provided in a central aperture of the susceptor and a fitting part provided on the rotary shaft side of the chamber.

Consequently, when misalignment occurs during placement of the susceptor inside the exchange box, a situation arises where the susceptor does not correctly fit the rotary shaft.

In the case where the susceptor is transported to the chamber after mounting is conducted on, for example, the exchange table inside the glove box, a problem identical to the aforementioned one arises in the case where the phase of the susceptor is inadvertently shifted on the exchange table.

As normal vapor-phase growth is impossible when the susceptor is not correctly set inside the chamber, it is indispensable to correctly set the susceptor in the chamber.

However, in the conventional example, alignment of the susceptor in the exchange box is conducted by a worker, and there is the problem that work efficiency is poor, because this work requires that care be taken.

Moreover, in the case where misalignment were to occur in the exchange box, it would be necessary to correct the alignment of the susceptor, and for this purpose, it would be necessary to temporarily return the susceptor to the exchange box to conduct alignment, and then again transport the susceptor.

However, there is the problem that when the susceptor is transported again, time is required, and production efficiency declines.

The present invention was made in order to solve the pertinent problems, and its object is to provide a vapor-phase growth apparatus in which susceptor misalignment problems do not occur during susceptor exchange.

### Means for Solving the Problems

(1) The vapor-phase growth apparatus of the present invention includes: a reaction furnace in which a susceptor is removably installed, and in which vapor-phase growth is conducted; a transport robot which transports the aforementioned susceptor; a glove box which accommodates the pertinent transport robot and the aforementioned reaction furnace; an exchange table which is set up inside the pertinent glove box, and on which a susceptor is temporarily mounted during susceptor replacement; and an exchange box which is provided in a side wall of the aforementioned glove box, and in which replacement of the aforementioned susceptor is conducted;

and wherein the aforementioned exchange table includes a positioning device which rotates upon mounting of the aforementioned susceptor, and which determines a susceptor position in a rotational direction by stopping at a prescribed rotational position.

(2) The vapor-phase growth apparatus recorded in (1) above, wherein the aforementioned positioning device includes: a rotary mechanism which rotates a susceptor mounted on an exchange table; a sensor which is provided near the aforementioned exchange table, and which detects markers provided on the aforementioned susceptor; and a controller which controls a rotational position of the aforementioned exchange table by inputting signals of the pertinent sensor.

### Effects of the Invention

With respect to the present invention, as the exchange table set up inside the glove box is provided with a positioning device which determines a susceptor position in a rotational direction, a worker is not needed to align the susceptor in the exchange box, work efficiency is increased, and there is no lowering of work efficiency due to alignment defects.

### BRIEF DESCRIPTION OF THE DRAWINGS

FIG. 1 is an explanatory view of the overall configuration of a vapor-phase growth apparatus of an embodiment of the present invention.

FIG. 2 is an explanatory view of a susceptor of an embodiment of the present invention.

FIG. 3 is an explanatory view of a positioning device of an embodiment of the present invention.

FIG. 4 is an explanatory view of a conventional vapor-phase growth apparatus.

### MODE FOR CARRYING OUT THE INVENTION

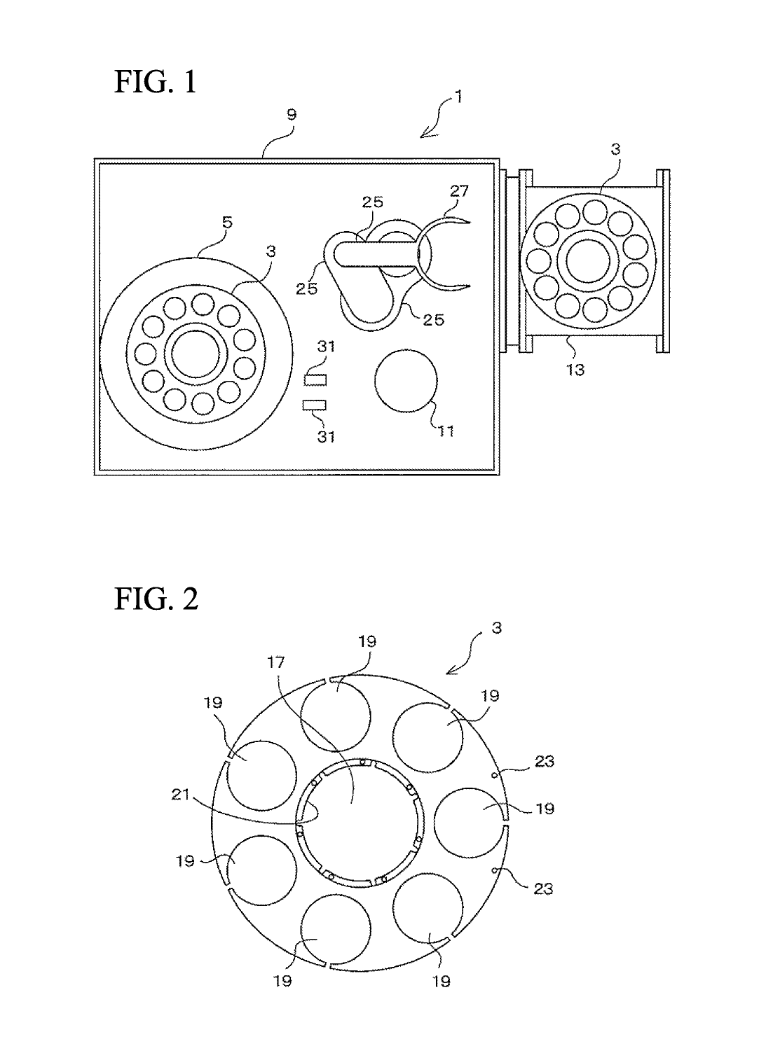

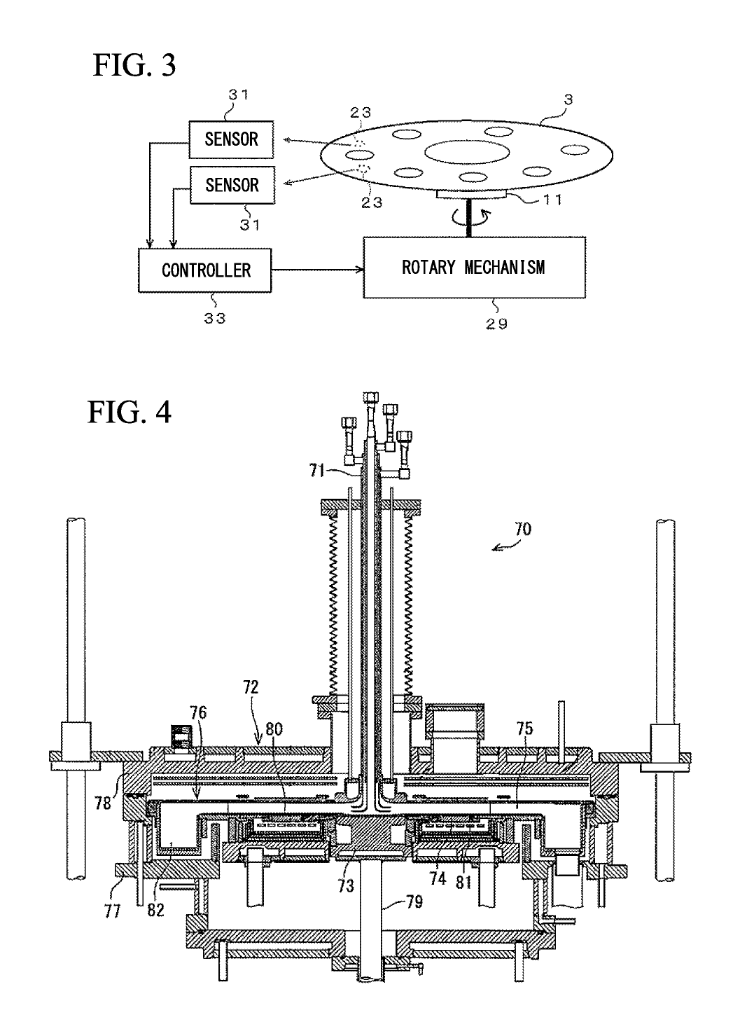

As shown in FIG. 1, a vapor-phase growth apparatus 1 of the present embodiment is provided with a reaction furnace 5 in which a susceptor 3 is removably installed, and in which vapor-phase growth is conducted, a transport robot (not illustrated in the drawing) which transports the susceptor 3, a glove box 9 which accommodates the transport robot and the reaction furnace 5, an exchange table 11 which is set up inside the glove box 9, and on which the susceptor 3 is temporarily mounted during replacement of the susceptor 3, and an exchange box 13 which is provided on a side wall of the glove box 9, and in which replacement of the susceptor 3 is conducted; wherein the exchange table 11 is provided with a positioning device 15 (see FIG. 3) which rotates upon mounting of the susceptor 3, and which determines a position of the susceptor 3 in a rotational direction by stopping at a prescribed rotational position.

The details are described as follows.

<Susceptor>

As shown in FIG. 2, the susceptor 3 is configured by a disk whose overall configuration is donut-shaped with an aperture 17 at the center.

This susceptor 3 is provided with multiple pockets 19 in which substrate mounting units are set. There is no particular limit on the number of pockets 19. For example, 11 pockets are illustrated in FIG. 1, whereas 7 pockets are illustrated in FIG. 2.

A fitting part 21 is provided in the central aperture 17 of the susceptor 3, and the susceptor 3 is structured so that the fitting part 21 formed in the aperture 17 fits onto the rotary shaft side on the reaction furnace 5 side.

As shown in FIG. 2, markers 23 are formed on the rear surface of the susceptor 3 on both sides of one of the pockets 19 that serves as alignment reference. By detecting the markers 23 by the below-described sensor 31, the position of this pocket 19 can be detected. The markers 23 are concavely shaped (e.g., ellipses of 10 mm×6 mm, with a depth of 5 mm) to an extent that enables identification by the sensor 31.

The substrate mounting unit that is set in the pocket 19 is rotatable, and a substrate on which a thin film is formed is mounted onto the substrate mounting unit. The susceptor 3 is structured so that when it is set in the reaction furnace 5, the entirety of the susceptor 3 revolves (rotates) by means of a drive mechanism that is not illustrated in the drawing, and the substrate mounting units rotate in tandem with this revolution.

<Reaction Furnace>

The reaction furnace 5 is for removable installation of the susceptor 3, and for conduct of vapor-phase growth. There are no particular limitations on the form of the reaction furnace 5, and, for example, the forms recorded in Patent Documents 1 and 2 can be applied.

To give a summary description of one form of the reaction furnace 5, the overall configuration has a flat cylindrical shape, and is provided with a chamber body on the lower half side, and a chamber cover that opens and closes the chamber body.

A nozzle for introduction of raw material gas is installed in the central region of the chamber body, enabling supply of raw material gas to a substrate mounted on the susceptor 3. With respect to introduction of raw material gas, for example, introduction may be conducted from above as in Patent Document 1, or from below as in Patent Document 2.

The peripheral edge of the chamber body constitutes a body flange, and contacts the cover flange of the chamber cover to enable airtight closure of the reaction furnace 5. The chamber cover is raised and lowered relative to the chamber body by a lift mechanism.

<Transport Robot>

A transport robot (not illustrated in the drawings) is installed inside the glove box, and transports the susceptor 3. With respect to the transport robot, as shown in FIG. 1, multiple arms 25 are rotatably connected by joints, and a holder 27 that holds the susceptor 3 is provided on the foremost arm 25.

By turning the respective arms 25, the transport robot is able to transport the susceptor 3 to the reaction furnace 5, the exchange table 11, and the exchange box 13, respectively.

<Glove Box>

The glove box 9 accommodates the transport robot and the reaction furnace 5. Nitrogen gas can be supplied to the glove box 9, and the interior of the box can be replaced with a nitrogen atmosphere.

An exchange box 13 for conducting exchange of the susceptor 3 is provided on a side face of the glove box. The exchange box 13 is connected to a vacuum pump and a nitrogen gas supply tube, and the atmosphere inside the exchange box 13 can be replaced with a nitrogen atmosphere.

<Exchange Table>

The exchange table 11 is set up inside the glove box 9, and the susceptor 3 is temporarily mounted thereon during replacement of the susceptor 3. A below-described positioning device 15 is incorporated into the exchange table 11.

<Positioning Device>

The positioning device 15 is provided with a rotary mechanism 29 which rotates the susceptor 3 mounted on the exchange table 11, a sensor 31 which is provided in the vicinity of the exchange table 11, and which detects the markers 23 provided on the susceptor 3, and a controller 33 which controls a rotational position of the exchange table 11 by input of signals from the sensor 31.

A description is now given of operations during exchange of the susceptor 3 in the present embodiment configured as described above.

A susceptor 3 for exchange is mounted inside the exchange box 13. In the conventional example, as positioning of the susceptor 3 is conducted at this time in the exchange box 13, a worker is required to conduct positional (phase) alignment of the susceptor 3. However, in the present embodiment, as alignment of the susceptor 3 is conducted on the exchange table 11, there is no need to conduct alignment during placement of the susceptor 3 in the exchange box 13.

When the susceptor 3 is placed in the exchange box 13, the transport robot holds the susceptor 3, transports it to the position of the exchange table 11, and mounts the susceptor 3 onto the exchange table 11. Upon mounting of the susceptor 3, the exchange table 11 is rotated, the sensor 31 detects the markers 23 on the rear surface of the susceptor 3, and detection signals are transmitted to the controller 33. The controller 33 inputs the detection signals from the sensor 31, controls the rotary mechanism 29 so that the marker detection position comes to the prescribed position, and stops the exchange table 11 at the prescribed position. 13y stopping the exchange table 11 at the prescribed position, positional (phase) alignment of the susceptor 3 mounted on the exchange table 11 is completed.

The sensor 31 projects a light beam onto the rear surface of the rotating susceptor 3, and the detector detects the reflected light that is reflected from the rear surface of the susceptor 3. By providing markers (concavities) on the rear surface of the susceptor 3, the existence or absence (intensity) of reflected light is perceived, and stoppage at the prescribed phase is conducted. When there is a plurality of markers 23, the reliability of marker detection is enhanced. With respect to the form of the markers 23, if diameter is on the order of sensor light spot diameter (several mm), and if depth is on the order of 5 mm, recognition by a sensor is feasible. By enabling recognition of the number or form of the markers 23, it is also possible to conduct susceptor identification.

When positional alignment of the susceptor 3 is completed, substrate mounting units and substrates or the like are set in the pockets 19 of the susceptor 3. When setting of the substrates or the like is completed, the susceptor 3 is then held by the transport robot, and transported to the reaction furnace 5, where installation is conducted by aligning the aperture 17 of the susceptor 3 with the rotary shaft of the reaction furnace 5. At this time, as the phase of the susceptor 3 has been aligned at the correct position with the exchange table 11, a failure of the susceptor 3 to meet the rotary shaft of the reaction furnace 5 due to misalignment of the susceptor 3 does not occur.

As described above, in the present embodiment, the following effects are obtained as a result of automatically conducting positional alignment of the susceptor 3 with the exchange table 11.

First, as there is no need for a worker to conduct positional alignment of the susceptor 3 with the exchange table 11, work efficiency is enhanced.

As the position of the susceptor 3 is automatically aligned at the correct position with the exchange table 11, failure to set the susceptor 3 due to misalignment does not occur during setting of the susceptor 3 in the reaction furnace 5.

With respect to this point, in the conventional example, in the case where the position of the susceptor 3 in the exchange box 13 is incorrect, the susceptor 3 would not be correctly set in the reaction furnace 5, and would have to be returned again to the exchange box 13 for alignment, and subsequently retransported, thereby wasting time and lowering productivity.

In contrast, as such wasted time does not occur in the present embodiment, there is the effect that productivity is enhanced.

Otherwise, in the foregoing embodiment, the markers 23 provided in the susceptor 3 are only used for recognizing the position of the susceptor 3.

However, by modifying the shape of the markers 23 by susceptor 3, it is also acceptable to enable not only recognition of the position of the susceptor 3, but also identification of the individual susceptor 3. If this is done, vapor-phase growth reaction can be carried out on the pertinent susceptors 3 under optimal conditions by preparing a vapor-phase growth program that presets the reaction conditions and the like by susceptor 3.

### INDUSTRIAL APPLICABILITY

The present invention relates in particular to semiconductor manufacturing devices that form film on compound semiconductors, and can be used to enhance the quality of semiconductors that are manufactured by the pertinent devices.

### DESCRIPTION OF THE REFERENCE NUMERALS

1: vapor-phase growth apparatus
3: susceptor
5: reaction furnace
9: glove box
11: exchange table
13: exchange box
15: positioning device
17: aperture
19: pocket
21: setting part
23: marker
25: arm
27: holder
29: rotary mechanism
31: sensor
33: controller
70: vapor-phase growth apparatus
71: gas inlet tube
72: chamber
73: susceptor
74: substrate holder
75: reaction chamber
77: chamber body
78: chamber cover
79: rotary drive shaft
80: substrate
81: heater

1. A vapor-phase growth apparatus, comprising: a reaction furnace in which a susceptor is removably installed, and in which vapor-phase growth is conducted; a transport robot which transports said susceptor; a glove box which accommodates the pertinent transport robot and said reaction furnace; an exchange table which is set up inside the pertinent glove box, and on which a susceptor is temporarily mounted during susceptor replacement; and an exchange box which is provided in a side wall of said glove box, and in which susceptor replacement is conducted;
and wherein said exchange table comprises a positioning device which rotates upon mounting of said susceptor, and which determines a position of said susceptor in a rotational direction by stopping at a prescribed rotational position.

2. The vapor-phase growth apparatus according to claim 1, wherein said positioning device comprises: a rotary mechanism which rotates a susceptor mounted on an exchange table; a sensor which is provided near said exchange table, and which detects markers provided on said susceptor; and a controller which controls a rotational position of said exchange table by inputting signals of the pertinent sensor.
